(19) United States
(12) Patent Application Publication
(10) Pub. No.: US 2026/0184963 A1
(43) Pub. Date: Jul. 2, 2026

(54) POLISHING LIQUID FOR CMP, POLISHING LIQUID SET FOR CMP, AND POLISHING METHOD

(71) Applicant: Resonac Corporation, Minato-ku, Tokyo (JP)

(72) Inventors: Yasushi KURATA, Minato-ku, Tokyo (JP); Tomohiro IWANO, Minato-ku, Tokyo (JP)

(21) Appl. No.: 18/857,078

(22) PCT Filed: Aug. 7, 2023
(86) PCT No.: PCT/JP2023/028805

§ 371 Date: Oct. 15, 2024

(51) Int. Cl. C09G 1/02; B24B 37/04; B24B 57/02; C09K 13/00

(52) U.S. Cl. CPC C09G 1/02; B24B 37/042; B24B 57/02; C09K 13/00

(57) ABSTRACT

A polishing liquid for CMP, the polishing liquid containing abrasive grains, a nitrogen-containing compound having an aromatic ring, and water, in which the abrasive grains include cerium-based particles, and the abrasive grains have a negative zeta potential. A polishing method including a step of polishing a surface to be polished using the polishing liquid for CMP.

### TECHNICAL FIELD

The present disclosure relates to a polishing liquid for CMP (chemical mechanical polishing), a polishing liquid set for CMP, a polishing method, and the like.

### BACKGROUND ART

In the field of semiconductor manufacturing, along with high performance improvement of ultra LSI devices, there is a limit in achieving both high integration and high speed using a miniaturization technique which is an extension of a conventional technique. Therefore, while miniaturization of a semiconductor element is in progress, a technique for achieving high integration also in a vertical direction (that is, a technique for multilayered wiring) is being developed.

One of the most important techniques in a process of manufacturing a device having a multilayered wiring structure is a CMP technique. The CMP technique is a technique to planarize the surface of a base substrate obtained by forming a thin film on a substrate by chemical vapor deposition (CVD) or the like. For example, to secure the focal depth of lithography, planarization processing by CMP is essential. When the surface of the base substrate has unevenness, there are disadvantages in that focusing in an exposure step becomes impossible and a fine wiring structure cannot be sufficiently formed. In addition, in the process of manufacturing a device, the CMP technique is also applied to a step of forming an element isolation (inter-element isolation, STI: shallow trench isolation) region by polishing a plasma oxide film (BPSG, HDP-SiO₂, p-TEOS, and the like); a step of forming an ILD film (an interlayer insulating film, an insulating film that electrically insulates metal members (wiring and the like) in the same layer); and a step of planarizing a plug (for example, an Al—Cu plug) after a film containing silicon oxide is embedded in a metal wiring.

CMP is usually performed using a device capable of supplying a polishing liquid onto a polishing pad. Then, the surface of the base substrate is polished by pressing the base substrate against the polishing pad while supplying the polishing liquid between the surface of the base substrate and the polishing pad. As described above, in the CMP technique, the polishing liquid is one of the elemental techniques, and various polishing liquids have been developed so far to obtain a high-performance polishing liquid (refer to, for example, Patent Literature 1 below).

Among the steps to which the CMP technique as described above is applied, particularly in the CMP step of the ILD film, it is necessary to polish silicon oxide at a high polishing rate. Therefore, in the CMP step of the ILD film, a silica-based polishing liquid (a polishing liquid using abrasive grains including silica-based particles) having a high polishing rate is mainly used (refer to, for example, Patent Literature 2 below). However, in the silica-based polishing liquid, it tends to be difficult to control polishing scratches that cause a defect. In addition, along with the recent miniaturization of wiring, it is desirable to reduce polishing scratches even in the CMP step of the ILD film, but unlike the CMP step of the insulating film for element isolation region, finish mirror polishing is not generally performed. Therefore, a study has been conducted to use a cerium-based polishing liquid (a polishing liquid using abrasive grains including cerium-based particles) generating fewer polishing scratches than those of the silica-based polishing liquid (refer to, for example, Patent Literature 3 below).

### CITATION LIST

### Patent Literature

Patent Literature 1: Japanese Unexamined Patent Publication No. 2008-288537

Patent Literature 2: Japanese Unexamined Patent Publication No. H9-316431

Patent Literature 3: Japanese Unexamined Patent Publication No. H10-102038

### SUMMARY OF INVENTION

### Technical Problem

When polishing a surface to be polished using abrasive grains, it is required that the abrasive grains hardly remain on the polished surface after polishing. Here, since silicon oxide of a material to be polished tends to have a negative zeta potential, when a surface to be polished containing silicon oxide is polished using abrasive grains having a negative zeta potential, the abrasive grains are less likely to remain on the polished surface after polishing due to electrostatic repulsion between the abrasive grains and the surface to be polished. On the other hand, since it is difficult to improve the polishing rate due to electrostatic repulsion between the abrasive grains and the surface to be polished, it may be difficult to achieve a high polishing rate of silicon oxide in the case of using abrasive grains having a negative zeta potential.

In addition, a polishing liquid for CMP can be used to planarize a surface to be polished by polishing a patterned wafer having an uneven pattern constituted of a convex portion (for example, a line portion) and a concave portion (for example, a space portion) to remove the convex portion. In this case, from the viewpoint of obtaining high planarity and the viewpoint of shortening a polishing time required for planarization, it may be required to achieve a high polishing rate ratio of silicon oxide at the convex portion in the patterned wafer having the uneven pattern with respect to silicon oxide in a blanket wafer having no uneven pattern. However, when abrasive grains having a negative zeta potential are used, it may be difficult to achieve such high polishing rate ratio due to, for example, difficulty in improving the polishing rate due to electrostatic repulsion between the abrasive grains and the convex portion.

An object of one aspect of the present disclosure is to provide a polishing liquid for CMP using abrasive grains having a negative zeta potential, in which the polishing liquid for CMP is capable of achieving a high polishing rate ratio of silicon oxide at a convex portion in a patterned wafer having an uneven pattern with respect to silicon oxide in a blanket wafer having no uneven pattern. An object of another aspect of the present disclosure is to provide a polishing liquid set for CMP for obtaining such polishing liquid for CMP. An object of another aspect of the present disclosure is to provide a polishing method using such polishing liquid for CMP.

### Solution to Problem

The present disclosure relates to the following [1] to [15] and the like in some aspects.

[1] A polishing liquid for CMP, the polishing liquid containing: abrasive grains; a nitrogen-containing compound having an aromatic ring; and water, in which the abrasive grains include cerium-based particles, and the abrasive grains have a negative zeta potential.

[2] The polishing liquid for CMP according to [1], in which the cerium-based particles contain cerium oxide.

[3] The polishing liquid for CMP according to [1] or [2], in which the nitrogen-containing compound includes a compound having an amino group bonded to an aromatic ring. [4] The polishing liquid for CMP according to [3], in which the nitrogen-containing compound includes anthranilic acid. [5] The polishing liquid for CMP according to any one of [1] to [4], in which the nitrogen-containing compound includes a compound having a hydroxyamide group bonded to an aromatic ring.

[6] The polishing liquid for CMP according to [5], in which the nitrogen-containing compound includes benzohydroxamic acid.

[7] The polishing liquid for CMP according to any one of [1] to [6], in which the nitrogen-containing compound includes an indole compound.

[8] The polishing liquid for CMP according to [7], in which the nitrogen-containing compound includes indole acetic acid.

[9] The polishing liquid for CMP according to any one of [1] to [8], in which the nitrogen-containing compound includes a quinoline compound.

[10] The polishing liquid for CMP according to [9], in which the nitrogen-containing compound includes quinaldic acid.

[11] The polishing liquid for CMP according to any one of [1] to [10], in which a content of the nitrogen-containing compound is 0.001 to 5% by mass.

[12] The polishing liquid for CMP according to any one of [1] to [11], in which pH is 4.0 to 9.0.

[13] A polishing liquid set for CMP, in which components of the polishing liquid for CMP according to any one of [1] to [12] are stored separately in a first liquid and a second liquid, in which the first liquid contains the abrasive grains and water, and the second liquid contains the nitrogen-containing compound and water.

[14] A polishing method including a step of polishing a surface to be polished using the polishing liquid for CMP according to any one of [1] to [12].

[15] The polishing method according to [14], in which the surface to be polished contains silicon oxide.

### Advantageous Effects of Invention

According to one aspect of the present disclosure, it is possible to provide a polishing liquid for CMP using abrasive grains having a negative zeta potential, in which the polishing liquid for CMP is capable of achieving a high polishing rate ratio of silicon oxide at a convex portion in a patterned wafer having an uneven pattern with respect to silicon oxide in a blanket wafer having no uneven pattern. According to another aspect of the present disclosure, it is possible to provide a polishing liquid set for CMP for obtaining such polishing liquid for CMP. According to another aspect of the present disclosure, it is possible to provide a polishing method using such polishing liquid for CMP.

### BRIEF DESCRIPTION OF DRAWINGS

FIG. 1 is a schematic cross-sectional view illustrating a process of polishing an ILD film.

### DESCRIPTION OF EMBODIMENTS

Hereinafter, embodiments of the present disclosure will be described in detail.

In the present specification, a numerical range indicated using “to” indicates a range including numerical values described before and after “to” as a minimum value and a maximum value, respectively. “A or more” of a numerical range means A and a range exceeding A. “A or less” of a numerical range means A and a range less than A. In a numerical range described stepwise in the present specification, an upper limit value or a lower limit value of a numerical range of a certain stage can be arbitrarily combined with an upper limit value or a lower limit value of a numerical range of another stage. In a numerical range described in the present specification, an upper limit value or a lower limit value of the numerical range may be replaced with a value shown in Examples. “A or B” may include either A or B, and may include both A and B. Materials exemplified in the present specification can be used alone or in combination of two or more kinds thereof unless otherwise specified. When a plurality of substances corresponding to each component are present in a composition, a content of each component in the composition means the total amount of the plurality of substances present in the composition unless otherwise specified. The term “layer” or “film” includes not only a structure having a shape formed on the entire surface but also a structure having a shape formed on a part thereof when observed in a plan view. The term “step” includes not only an independent step but also a step that cannot be clearly distinguished from other steps as long as the intended action of the step is achieved.

### <Polishing Liquid for CMP>

The polishing liquid for CMP (hereinafter, in some cases, simply referred to as a “polishing liquid”) of the present embodiment contains abrasive grains, a nitrogen-containing compound having an aromatic ring (hereinafter, in some cases, referred to as a “nitrogen-containing aromatic compound”), and water. The abrasive grains include cerium-based particles (particles containing a cerium-based compound), and a zeta potential of the abrasive grains is negative.

According to the polishing liquid of the present embodiment, it is possible to achieve a high polishing rate ratio of silicon oxide at a convex portion in a patterned wafer having an uneven pattern (an uneven pattern constituted of a convex portion (for example, a line portion) and a concave portion (for example, a space portion)) with respect to silicon oxide in a blanket wafer having no uneven pattern, and for example, it is possible to achieve a high polishing rate ratio of silicon oxide at the convex portion in a region of Line/Space (L/S)=20 μm/80 μm of the patterned wafer with respect to silicon oxide in the blanket wafer having no uneven pattern. According to the polishing liquid of the present embodiment, in an evaluation method described in Examples described later, for example, 0.70 or more (preferably 0.90 or more, 1.00 or more, 1.50 or more, 1.70 or more, or the like) can be obtained as the polishing rate ratio of silicon oxide at the convex portion in the region of L/S=20 μm/80 μm of the patterned wafer with respect to silicon oxide in the blanket wafer. By obtaining a high polishing rate ratio of silicon oxide at the convex portion in the patterned wafer having the uneven pattern with respect to silicon oxide in the blanket wafer having no uneven pattern, high planarity can be realized as a characteristic that the convex portion can be selectively polished.

A factor capable of achieving a high polishing rate ratio of silicon oxide at the convex portion in the patterned wafer with respect to silicon oxide in the blanket wafer is not necessarily clear, but is presumed to be as follows. However, the factor is not limited to the following contents.

That is, when a surface to be polished containing silicon oxide is polished using the abrasive grains having a negative zeta potential, it may be difficult to achieve a high polishing rate of silicon oxide due to electrostatic repulsion between the abrasive grains and the surface to be polished. In particular, in the patterned wafer, a high pressure is easily applied to the convex portion, but it may be difficult to obtain the polishing rate corresponding to the pressure applied to the convex portion.

On the other hand, according to the polishing liquid of the present embodiment, by using the nitrogen-containing aromatic compound together with the cerium-based particles, it is possible to obtain effects such that an interaction between the cerium-based particles and silicon oxide of the convex portion tends to increase (for example, a chemical reaction between the cerium-based particles in the polishing liquid and silicon oxide of the convex portion (a reaction derived from bonding of Si—O—Ce) is likely to be promoted), and electrostatic repulsion between the abrasive grains and the surface to be polished is easily suppressed by decreasing an absolute value of a negative charge of the surface to be polished containing silicon oxide. Therefore, it is presumed that, in the polishing of the patterned wafer, since the polishing rate corresponding to the pressure applied to the convex portion is easily obtained, a high polishing rate of silicon oxide at the convex portion can be achieved, and a high polishing rate ratio of silicon oxide at the convex portion in the pattern wafer with respect to silicon oxide in the blanket wafer can be achieved.

According to the findings of the present inventors, when abrasive grains having a negative zeta potential are used, even if a high polishing rate of silicon oxide is achieved in polishing of a blanket wafer having no uneven pattern, it may be difficult to achieve a high polishing rate of silicon oxide at a convex portion in polishing of a patterned wafer having an uneven pattern. Therefore, regarding a polishing liquid using the abrasive grains having a negative zeta potential, it may be required to achieve a high polishing rate of silicon oxide at the convex portion in polishing of the patterned wafer having the uneven pattern. According to one form of the polishing liquid of the present embodiment, it is possible to achieve a high polishing rate of silicon oxide at a convex portion in polishing of a patterned wafer having an uneven pattern, and for example, it is possible to achieve a high polishing rate of silicon oxide at the convex portion in polishing of a region of Line/Space (L/S)=20 μm/80 μm in the patterned wafer. According to one form of the polishing liquid of the present embodiment, in an evaluation method described in Examples described later, for example, 100 nm/min or more (preferably 150 nm/min or more, 200 nm/min or more, 250 nm/min or more, 300 nm/min or more, 350 nm/min or more, or the like) can be obtained as the polishing rate of silicon oxide of the convex portion in the region of L/S=20 μm/80 μm.

According to one form of the polishing liquid of the present embodiment, it is possible to achieve a high polishing rate of silicon oxide at the convex portion in polishing of the region of L/S=20 μm/80 μm in the patterned wafer while achieving high-rate polishing of silicon oxide in the blanket wafer having no uneven pattern. According to one form of the polishing liquid of the present embodiment, in an evaluation method described in Examples described later, for example, 40 nm/min or more (preferably 50 nm/min or more, 80 nm/min or more, 100 nm/min or more, 150 nm/min or more, 200 nm/min or more, 230 nm/min or more, or the like) can be obtained as the polishing rate of silicon oxide in the blanket wafer.

In the step of forming an element isolation region, it may be required to suppress a polishing rate of a silicon nitride film used as a stopper which is an underlayer of a silicon oxide film, and high polishing selectivity of silicon oxide with respect to silicon nitride (polishing rate of silicon oxide/polishing rate of silicon nitride) may be required. According to one form of the polishing liquid of the present embodiment, a sufficiently low polishing rate of silicon nitride can be obtained, and high polishing selectivity of silicon oxide with respect to silicon nitride can be obtained. This case is suitable for polishing when forming the element isolation region. According to one form of the polishing liquid of the present embodiment, in an evaluation method described in Examples described later, for example, 100 nm/min or less (preferably 50 nm/min or less, 30 nm/min or less, 20 nm/min or less, 15 nm/min or less, or the like) can be obtained as the polishing rate of silicon nitride in the blanket wafer.

The polishing liquid of the present embodiment can be used for CMP of a semiconductor wafer material, and can be used, for example, for polishing a silicon oxide film provided on a surface of a semiconductor wafer. The polishing liquid of the present embodiment can be used in the CMP step of the ILD film. According to one form of the polishing liquid of the present embodiment, it is possible to suppress aggregation of abrasive grains and occurrence of polishing scratches and obtain high planarity while obtaining a high polishing rate.

### (Abrasive Grains)

In the polishing liquid of the present embodiment, the abrasive grains include cerium-based particles (particles containing a cerium-based compound). By using the cerium-based particles as the abrasive grains, it is easy to obtain a high polishing rate of silicon oxide at the convex portion in the patterned wafer while reducing polishing scratches generated on the polished surface.

Examples of the cerium-based compound of the cerium-based particles include cerium oxide, cerium hydroxide, ammonium cerium nitrate, cerium acetate, cerium sulfate hydrate, cerium bromate, cerium bromide, cerium chloride, cerium oxalate, cerium nitrate, and cerium carbonate. The cerium-based particles may contain cerium oxide from the viewpoint of easily obtaining a high polishing rate of silicon oxide at the convex portion (such as a convex portion in the region of L/S=20 μm/80 μm; the same applies below) in the patterned wafer and the viewpoint of easily obtaining a polished surface having few polishing scratches and excellent planarity. Cerium oxide may be CeO₂ (cerium (IV) oxide, ceria), and may be Ce₂O₃ (cerium (III) oxide).

Cerium oxide particles (particles containing cerium oxide) may contain polycrystalline cerium oxide having a crystal grain boundary. Particles containing polycrystalline cerium oxide have a property that active surfaces appear one after another as the particles become fine during polishing, and a high polishing rate of silicon oxide at the convex portion in the patterned wafer can be highly maintained.

Examples of a method for producing the cerium oxide particles include a firing method; and an oxidation method using hydrogen peroxide. In the case of firing, the temperature during firing may be 350 to 900° C. When the cerium oxide particles are aggregated, the particles may be mechanically pulverized. The pulverization method may be, for example, dry pulverization using a jet mill or the like, or wet pulverization using a planetary bead mill or the like. As the jet mill, for example, a jet mill described in “Kagaku Kougaku Ronbunshu (Collection of Chemical Engineering Papers)”, Vol. 6, No. 5, (1980), page 527 to 532 can be used.

A zeta potential (surface potential) of the abrasive grains in the polishing liquid is negative (zeta potential is less than 0 mV). The zeta potential of the abrasive grains may be −1 mV or less, −5 mV or less, −10 m V or less, −20 m V or less, −30 m V or less, −40 m V or less, −45 m V or less, −50 m V or less, or −55 m V or less. The zeta potential of the abrasive grains may be −100 mV or more, −90 mV or more, −80 mV or more, −70 m V or more, −60 m V or more, −55 m V or more, −50 m V or more, or −45 m V or more. From these viewpoints, the zeta potential of the abrasive grains may be −100 m V or more and less than 0 mV, −80 m V or more and less than 0 mV, −60 m V or more and less than 0 mV, −100 mV to −20 mV, −80 m V to −20 mV, −60 m V to −20 mV, −100 mV to −40 mV, −80 mV to −40 m V, or −60 m V to −40 m V.

The zeta potential of the abrasive grains can be measured using, for example, a dynamic light scattering zeta potential measuring device (for example, trade name: DelsaNano C manufactured by Beckman Coulter Inc.). The zeta potential of the abrasive grains can be adjusted using an additive. For example, by bringing an anionic dispersant into contact with the abrasive grains, abrasive grains having a negative zeta potential can be obtained. Examples of the anionic dispersant include a polymer having at least one selected from the group consisting of a carboxy group and a carboxylate group; and ammonium dihydrogen phosphate. Examples of the polymer having at least one selected from the group consisting of a carboxy group and a carboxylate group include ammonium polyacrylate, polyacrylic acid, a copolymer of acrylic acid and alkyl acrylate, a copolymer of acrylic acid and methacrylic acid, and salts thereof. From the viewpoint of easily obtaining a high polishing rate of silicon oxide at the convex portion in the patterned wafer, the viewpoint of easily achieving a high polishing rate ratio of silicon oxide at the convex portion in the patterned wafer with respect to silicon oxide in the blanket wafer, and the viewpoint of easily suppressing the polishing rate of silicon nitride, the polishing liquid of the present embodiment may contain, as the anionic dispersant brought into contact with the abrasive grains, at least one selected from the group consisting of a polymer having at least one selected from the group consisting of a carboxy group and a carboxylate group, and ammonium dihydrogen phosphate.

The average particle diameter of the abrasive grains may be 50 nm or more, 70 nm or more, 80 nm or more, 100 nm or more, more than 100 nm, 105 nm or more, 110 nm or more, 115 nm or more, 120 nm or more, 125 nm or more, 130 nm or more, 135 nm or more, or 140 nm or more, from the viewpoint of easily obtaining a high polishing rate of silicon oxide at the convex portion in the patterned wafer and the viewpoint of easily achieving high-rate polishing of silicon oxide in the blanket wafer having no uneven pattern. The average particle diameter of the abrasive grains may be 500 nm or less, 400 nm or less, 300 nm or less, 200 nm or less, 180 nm or less, 150 nm or less, or 140 nm or less, from the viewpoint of easily suppressing occurrence of polishing scratches. From these viewpoints, the average particle diameter of the abrasive grains may be 50 to 500 nm, 50 to 200 nm, 50 to 150 nm, 70 to 500 nm, 70 to 200 nm, 70 to 150 nm, 100 to 500 nm, 100 to 200 nm, or 100 to 150 nm.

The “average particle diameter of the abrasive grains” means a median value of a volume distribution obtained by measuring a sample in which the abrasive grains are dispersed with a particle diameter distribution measuring device (for example, a laser diffraction/scattering type particle diameter distribution measuring device), and can be measured using trade name: Microtrac MT3300EXII manufactured by MicrotracBEL Corp, or the like. For example, a sample is prepared by dispersing the abrasive grains in water so as to be adjusted to the content of the abrasive grains having scattering intensity in a range suitable for measurement, this sample is set in a measuring device, and the average particle diameter is measured. In the case of measuring the particle diameter of the abrasive grains in the polishing liquid, a sample is prepared by adjusting the content of the abrasive grains in the polishing liquid so as to obtain the content of the abrasive grains having scattering intensity in a range suitable for measurement, and measurement can be performed by the same method using this sample. By adjusting the average particle diameter of the abrasive grains, a high polishing rate and low scratch characteristics of silicon oxide according to the particle diameter of the abrasive grains can be efficiently obtained.

The content of the abrasive grains may be in the following range based on the total mass of the polishing liquid from the viewpoint of excellent balance between the polishing rate of silicon oxide at the convex portion in the patterned wafer and dispersion stability of the abrasive grains. The content of the abrasive grains may be 0.01% by mass or more, 0.05% by mass or more, 0.1% by mass or more, 0.2% by mass or more, 0.3% by mass or more, 0.4% by mass or more, or 0.5% by mass or more. The content of the abrasive grains may be 10% by mass or less, 5% by mass or less, 3% by mass or less, 2.5% by mass or less, 2% by mass or less, 1.8% by mass or less, 1.5% by mass or less, 1.2% by mass or less, 1% by mass or less, 0.8% by mass or less, 0.6% by mass or less, or 0.5% by mass or less. From these viewpoints, the content of the abrasive grains may be 0.01 to 10% by mass, 0.01 to 3% by mass, 0.01 to 1% by mass, 0.05 to 10% by mass, 0.05 to 3% by mass, 0.05 to 1% by mass, 0.1 to 10% by mass, 0.1 to 3% by mass, or 0.1 to 1% by mass.

### (Nitrogen-Containing Aromatic Compound)

The polishing liquid of the present embodiment contains a nitrogen-containing aromatic compound (nitrogen-containing compound having an aromatic ring). The nitrogen-containing aromatic compound may have an aromatic ring containing a nitrogen atom and may have an aromatic ring not containing a nitrogen atom.

The nitrogen-containing aromatic compound may have a monocyclic aromatic ring and a polycyclic aromatic ring (a fused ring in which two or more monocyclic aromatic rings are fused, a fused ring in which one or more monocyclic non-aromatic rings are fused to one or more monocyclic aromatic rings, and the like).

Examples of the monocyclic aromatic ring include a benzene ring, a furan ring, a thiophene ring, a pyrrole ring, a pyrazole ring, an oxazole ring, an isoxazole ring, a thiazole ring, an imidazole ring, a pyridine ring, a pyridazine ring, a pyrimidine ring, and a pyrazine ring.

Examples of the fused ring in which two or more monocyclic aromatic rings are fused include a naphthalene ring, an anthracene ring, a benzofuran ring, an isobenzofuran ring, an indole ring, an isoindole ring, a benzothiophene ring, a benzimidazole ring, an indazole ring, a benzoxazole ring, a benzisoxazole ring, a benzothiazole ring, a quinoline ring, an isoquinoline ring, a quinoxaline ring, an acridine ring, a quinazoline ring, a cinnoline ring, a phthalazine ring, and a carbazole ring.

Examples of the fused ring in which one or more monocyclic non-aromatic rings are fused to one or more monocyclic aromatic rings include an indane ring, a fluorene ring, and a tetralin ring.

The nitrogen-containing aromatic compound may have a heterocyclic ring and may have a heterocyclic ring containing a nitrogen atom, as an aromatic ring, from the viewpoint of easily achieving a high polishing rate ratio of silicon oxide at the convex portion (such as a convex portion in the region of L/S=20 μm/80 μm, the same applies below) in the patterned wafer with respect to silicon oxide in the blanket wafer and the viewpoint of easily achieving a high polishing rate of silicon oxide at the convex portion in the patterned wafer. The nitrogen-containing aromatic compound may have a carbocyclic ring (non-heterocyclic ring) and may have a carbocyclic ring (non-heterocyclic ring) not containing a nitrogen atom, as an aromatic ring, from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer. The nitrogen-containing aromatic compound may have at least one selected from the group consisting of a monocyclic aromatic ring and a fused ring in which two or more monocyclic aromatic rings are fused, and may have at least one selected from the group consisting of a benzene ring (a monocyclic aromatic ring), an indole ring, and a quinoline ring, from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer.

The aromatic ring may have a substituent and may not have a substituent (may be unsubstituted). The aromatic ring may have a single substituent and may have a plurality of substituents. The aromatic ring may have a substituent containing a nitrogen atom, may not have a substituent containing a nitrogen atom, may have a substituent not containing a nitrogen atom, and may not have a substituent not containing a nitrogen atom. Examples of the substituent include a substituted or unsubstituted alkyl group, a hydroxy group, a carboxy group, a carboxylate group, an aldehyde group, an alkoxy group, an amino group, an amide group, a hydroxyamide group, a nitro group, a cyano group, a mercapto group, and a halogeno group (a fluoro group, a chloro group, a bromo group, an iodo group, and the like). Examples of the substituent that substitutes for a hydrogen atom of an alkyl group include a hydroxy group, a carboxy group, a carboxylate group, an aldehyde group, an alkoxy group, an amino group, an amide group, a hydroxyamide group, a nitro group, a cyano group, a mercapto group, and a halogeno group (a fluoro group, a chloro group, a bromo group, an iodo group, and the like).

The nitrogen-containing aromatic compound may include a compound having at least one selected from the group consisting of a carboxy group, a carboxylate group, an amino group, and a hydroxyamide group, and may include a compound having at least one selected from the group consisting of a carboxy group, a carboxylate group, an amino group, and a hydroxyamide group as a substituent directly bonded to an aromatic ring, from the viewpoint of easily achieving a high polishing rate ratio of silicon oxide at the convex portion in the pattern wafer with respect to silicon oxide in the blanket wafer and the viewpoint of easily obtaining a high polishing rate of silicon oxide at the convex portion in the patterned wafer. The nitrogen-containing aromatic compound may include a compound not having at least one selected from the group consisting of a carboxy group, a carboxylate group, an amino group, and a hydroxyamide group.

Examples of the nitrogen-containing aromatic compound include a compound having an amino group, a compound having a hydroxyamide group, an indole compound (a compound having an indole ring), a quinoline compound (a compound having a quinoline ring), and a pyridine compound (a compound having a pyridine ring).

Examples of the compound having an amino group include aniline and anthranilic acid. The compound having an amino group may include a compound having an amino group bonded to an aromatic ring (for example, a monocyclic benzene ring), may include a compound having at least one selected from the group consisting of a carboxy group and a carboxylate group and an amino group, and may include a compound having at least one selected from the group consisting of a carboxy group and a carboxylate group and an amino group as a functional group bonded to an aromatic ring (for example, a monocyclic benzene ring), from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer.

Examples of the compound having a hydroxyamide group include benzohydroxamic acid. The compound having a hydroxyamide group may include a compound having a hydroxyamide group bonded to an aromatic ring (for example, a monocyclic benzene ring) from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer.

Examples of the indole compound include indole, indole acid (indole acetic acid, indole propionic acid, and the like), alkylindole (methylindole and the like), phenylindole, hydroxyindole, carboxyindole, alkoxyindole, aminoindole, nitroindole, nitrile indole, and chloroindole.

Examples of the quinoline compound include quinoline, quinolinol, quinoline carboxylic acid (quinaldic acid and the like), aminoquinoline, and mercaptoquinoline.

Examples of the pyridine compound include pyridine, hydroxypyridine, aminopyridine, carboxypyridine (picolinic acid, nicotinic acid, isonicotinic acid, and the like), hydroxypyridinecarboxylic acid (hydroxypicolinic acid), aminopyridinecarboxylic acid (aminopicolinic acid), and cyanopyridine.

The nitrogen-containing aromatic compound may include at least one selected from the group consisting of a compound having an amino group, a compound having a hydroxyamide group, an indole compound, and a quinoline compound, may include at least one selected from the group consisting of a compound having an amino group bonded to an aromatic ring, a compound having a hydroxyamide group bonded to an aromatic ring, an indole compound, and a quinoline compound, and may include at least one selected from the group consisting of anthranilic acid, benzohydroxamic acid, indoleacetic acid, and quinaldinic acid, from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer. That is, the nitrogen-containing aromatic compound may be a form including a compound having an amino group bonded to an aromatic ring, a form including anthranilic acid, a form including a compound having a hydroxyamide group bonded to an aromatic ring, a form including benzohydroxamic acid, a form including an indole compound, a form including indole acetic acid, a form including a quinoline compound, or a form including quinaldic acid. The nitrogen-containing aromatic compound may include a compound other than a picolinic acid compound from the viewpoint of easily achieving a high polishing rate ratio of silicon oxide at the convex portion in the patterned wafer with respect to silicon oxide in the blanket wafer and the viewpoint of easily obtaining a high polishing rate of silicon oxide at the convex portion in the patterned wafer.

As the content of the nitrogen-containing aromatic compound, the content of a compound having an amino group bonded to the aromatic ring, the content of anthranilic acid, the content of a compound having a hydroxyamide group bonded to the aromatic ring, the content of benzohydroxamic acid, the content of an indole compound, the content of an indoleacetic acid, the content of a quinoline compound, or the content of quinaldic acid, a content A may be in the following range based on the total mass of the polishing liquid. The content A may be 0.0001% by mass or more, 0.0005% by mass or more, 0.001% by mass or more, 0.003% by mass or more, 0.005% by mass or more, 0.008% by mass or more, 0.01% by mass or more, 0.015% by mass or more, 0.02% by mass or more, 0.025% by mass or more, 0.03% by mass or more, 0.035% by mass or more, 0.04% by mass or more, 0.045% by mass or more, or 0.05% by mass or more, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, and the viewpoint of easily suppressing the polishing rate of silicon nitride. The content A may be 5% by mass or less, 3% by mass or less, 1% by mass or less, 0.8% by mass or less, 0.5% by mass or less, 0.4% by mass or less, 0.3% by mass or less, 0.2% by mass or less, 0.1% by mass or less, 0.09% by mass or less, 0.08% by mass or less, 0.07% by mass or less, 0.06% by mass or less, 0.05% by mass or less, 0.045% by mass or less, 0.04% by mass or less, 0.035% by mass or less, 0.03% by mass or less, 0.025% by mass or less, 0.02% by mass or less, 0.015% by mass or less, 0.01% by mass or less, less than 0.01%, 0.008% by mass or less, or 0.005% by mass or less, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, the viewpoint of easily suppressing the polishing rate of silicon nitride, and the viewpoint of easily achieving excellent dispersion stability of the abrasive grains. From these viewpoints, the content A may be 0.0001 to 5% by mass, 0.0001 to 1% by mass, 0.0001 to 0.1% by mass, 0.0001 to 0.015% by mass, 0.0001 to 0.008% by mass, 0.001 to 5% by mass, 0.001 to 1% by mass, 0.001 to 0.1% by mass, 0.001 to 0.015% by mass, 0.001 to 0.008% by mass, 0.008 to 5% by mass, 0.008 to 1% by mass, 0.008 to 0.1% by mass, 0.008 to 0.015% by mass, 0.015 to 5% by mass, 0.015 to 1% by mass, or 0.015 to 0.1% by mass. The content of the nitrogen-containing aromatic compound is the total amount of compounds corresponding to the nitrogen-containing aromatic compound, and the content of a compound having an amino group bonded to an aromatic ring is the total amount of compounds corresponding to compounds having an amino group bonded to an aromatic ring, and the same applies to other similar expressions. The same applies to the following expressions.

As a mass ratio of the content of the nitrogen-containing aromatic compound with respect to the content of the abrasive grains (nitrogen-containing aromatic compound/abrasive grains), a mass ratio of the content of the compound having an amino group bonded to an aromatic ring with respect to the content of the abrasive grains (compound having an amino group bonded to an aromatic ring/abrasive grains), a mass ratio of the content of anthranilic acid with respect to the content of the abrasive grains (anthranilic acid/abrasive grains), a mass ratio of the content of the compound having a hydroxyamide group bonded to an aromatic ring with respect to the content of the abrasive grains (compound having a hydroxyamide group bonded to an aromatic ring/abrasive grains), a mass ratio of the content of benzohydroxamic acid with respect to the content of the abrasive grains (benzohydroxamic acid/abrasive grains), a mass ratio of the content of the indole compound with respect to the content of the abrasive grains (indole compound/abrasive grains), a mass ratio of the content of indole acetic acid with respect to the content of the abrasive grains (indole acetic acid/abrasive grains), a mass ratio of the content of the quinoline compound with respect to the content of the abrasive grains (quinoline compound/abrasive grains), or a mass ratio of the content of quinaldic acid with respect to the content of the abrasive grains (quinaldic acid/abrasive grains), a mass ratio B may be in the following range. The mass ratio B may be 0.001 or more, 0.002 or more, 0.003 or more, 0.005 or more, 0.008 or more, 0.01 or more, 0.015 or more, 0.02 or more, 0.025 or more, 0.03 or more, 0.035 or more, 0.04 or more, 0.05 or more, 0.08 or more, or 0.1 or more, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, and the viewpoint of easily suppressing the polishing rate of silicon nitride. The mass ratio B may be 1 or less, less than 1, 0.8 or less, 0.6 or less, 0.5 or less, 0.4 or less, 0.3 or less, 0.2 or less, 0.1 or less, 0.08 or less, 0.05 or less, 0.04 or less, 0.035 or less, 0.03 or less, 0.025 or less, 0.02 or less, 0.015 or less, or 0.01 or less, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, the viewpoint of easily suppressing the polishing rate of silicon nitride, and the viewpoint of easily achieving excellent dispersion stability of the abrasive grains. From these viewpoints, the mass ratio B may be 0.001 to 1, 0.001 to 0.3, 0.001 to 0.1, 0.001 to 0.05, 0.001 to 0.03, 0.001 to 0.015, 0.005 to 1, 0.005 to 0.3, 0.005 to 0.1, 0.005 to 0.05, 0.005 to 0.03, 0.005 to 0.015, 0.015 to 1, 0.015 to 0.3, 0.015 to 0.1, 0.015 to 0.05, 0.015 to 0.03, 0.03 to 1, 0.03 to 0.3, 0.03 to 0.1, or 0.03 to 0.05.

### (Other Additives)

The polishing liquid of the present embodiment may further contain other additive (a component not corresponding to the above-described components) according to desired characteristics. Examples of such component include a nonionic polymer; a cationic compound; a pH adjusting agent described later; a polar solvent such as ethanol and acetone; and a cyclic monocarboxylic acid.

The polishing liquid of the present embodiment may contain a compound a having a molecular weight of 100000 or less and having four or more hydroxy groups, and may not contain the compound a. The content of the compound a may be 0.01% by mass or less, less than 0.01% by mass, 0.001% by mass or less, 0.0001% by mass or less, or substantially 0% by mass based on the total mass of the polishing liquid. The polishing liquid of the present embodiment may contain a compound b having four or more amino groups, and may not contain the compound b. The content of the compound b may be 0.001% by mass or less, less than 0.001% by mass, 0.0001% by mass or less, 0.00001% by mass or less, or substantially 0% by mass based on the total mass of the polishing liquid. The mass ratio of the content of the compound a with respect to the content of the compound b (compound a/compound b) may be 0.10 or less or less than 0.10.

### (Water)

The water is not particularly limited, but may include at least one selected from the group consisting of deionized water, ion-exchanged water, and ultrapure water.

(pH)

The pH of the polishing liquid of the present embodiment may be in the following range. The pH may be 12.0 or less, 11.0 or less, 10.5 or less, less than 10.5, 10.0 or less, less than 10.0, 9.5 or less, 9.0 or less, less than 9.0, 8.8 or less, 8.5 or less, 8.2 or less, 8.1 or less, 8.0 or less, less than 8.0, 7.8 or less, 7.6 or less, 7.5 or less, 7.2 or less, 7.0 or less, less than 7.0, 6.9 or less, 6.8 or less, 6.7 or less, 6.5 or less, 6.3 or less, 6.2 or less, 6.1 or less, 6.0 or less, less than 6.0, 5.9 or less, 5.7 or less, 5.5 or less, less than 5.5, 5.4 or less, 5.3 or less, 5.2 or less, 5.0 or less, less than 5.0, or 4.9 or less, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, and the viewpoint of easily suppressing the polishing rate of silicon nitride. The pH may be 4.0 or more, 4.5 or more, 4.9 or more, 5.0 or more, more than 5.0, 5.2 or more, 5.3 or more, 5.4 or more, 5.5 or more, more than 5.5, 5.7 or more, 5.9 or more, 6.0 or more, more than 6.0, 6.1 or more, 6.2 or more, 6.3 or more, 6.5 or more, 6.7 or more, 6.8 or more, 6.9 or more, 7.0 or more, more than 7.0, 7.2 or more, 7.5 or more, 7.6 or more, 7.8 or more, 8.0 or more, more than 8.0, or 8.1 or more, from the viewpoint of easily achieving a high polishing rate ratio of silicon oxide at the convex portion in the patterned wafer with respect to silicon oxide in the blanket wafer, the viewpoint of easily obtaining a high polishing rate of silicon oxide at the convex portion in the patterned wafer, the viewpoint of easily suppressing the polishing rate of silicon nitride, and the viewpoint of easily achieving excellent dispersion stability of the abrasive grains. From these viewpoints, the pH may be 4.0 to 12.0, 4.0 to 9.0, 4.0 to 8.0, 4.0 to 7.0, 4.0 to 6.0, 5.0 to 12.0, 5.0 to 9.0, 5.0 to 8.0, 5.0 to 7.0, 5.0 to 6.0, 6.0 to 12.0, 6.0 to 9.0, 6.0 to 8.0, 6.0 to 7.0, 7.0 to 12.0, 7.0 to 9.0, 7.0 to 8.0, 8.0 to 12.0, or 8.0 to 9.0. The pH can be measured by a method described in Examples. Regarding the lower limit of the pH, it is presumed that, when the pH is in the above-described range, the zeta potential of the abrasive grains is easily maintained negative within a range in which electrostatic repulsion between the abrasive grains and the surface to be polished is not excessively strengthened, and electrostatic repulsion between the abrasive grains is easily and suitably maintained, so that excellent dispersion stability of the abrasive grains is easily achieved. However, the factor is not limited to such contents.

Since the pH can vary depending on the type of a compound used as an additive, a pH adjusting agent may be used to adjust the pH to the above range. The pH adjusting agent is not particularly limited, and examples thereof include acids such as nitric acid, sulfuric acid, hydrochloric acid, phosphoric acid, and boric acid; and bases such as sodium hydroxide, ammonia (for example, ammonia water), potassium hydroxide, and calcium hydroxide. The nitrogen-containing aromatic compound, other additive, or the like may be used for pH adjustment. From the viewpoint of improving productivity, the polishing liquid may be prepared without using the pH adjusting agent, and this polishing liquid may be directly applied to CMP.

### <Preparation Method and Use Method of Polishing Liquid>

The polishing liquid of the present embodiment can be classified into (a) normal type, (b) concentration type, and (c) multiple liquid type (for example, two liquid type, a polishing liquid set for CMP), and a preparation method and a use method differ depending on the type. The (a) normal type is a polishing liquid that can be used as it is without being subjected to a pretreatment such as dilution at the time of polishing. The (b) concentration type is a polishing liquid in which the components are concentrated as compared with the (a) normal type considering convenience in storage and transportation. The (c) multiple liquid type is a polishing liquid in which the components are divided into a plurality of liquids (for example, the components are divided into a first liquid containing a certain component and a second liquid containing other component) at the time of storage or transportation, and these liquids are mixed and used at the time of use.

The (a) normal type can be obtained by dissolving or dispersing abrasive grains and additives in water which is a main dispersing medium. The polishing liquid can be prepared using, for example, a stirrer, a homogenizer, an ultrasonic disperser, a wet ball mill, or the like. Note that a treatment of micronizing the abrasive grains may be performed in the process of preparing the polishing liquid so that the average particle diameter of the abrasive grains falls within a desired range. The treatment of micronizing the abrasive grains can be performed by a sedimentation classification method or a method using a high-pressure homogenizer. The sedimentation classification method is a method including a step of forcibly settling a slurry containing abrasive grains using a centrifuge and a step of taking out only a supernatant liquid. On the other hand, the method using a high-pressure homogenizer is a method in which abrasive grains in a dispersion medium collide with each other at high pressure.

The (b) concentration type is diluted with water immediately before use so that the components have a desired content. After the dilution, stirring may be performed for an arbitrary time until liquid characteristics (pH, particle diameter of abrasive grains, or the like) and polishing characteristics (polishing rate of silicon oxide, polishing selection ratio of silicon oxide with respect to silicon nitride, or the like) equivalent to those of the (a) normal type are obtained. In such (b) concentration type, since the volume decreases according to a degree of concentration, costs for storage and transportation can be reduced.

The concentration ratio may be 1.5 times or more, 2 times or more, 3 times or more, or 5 times or more. When the concentration ratio is 1.5 times or more, advantages regarding storage and transportation tend to be easily obtained as compared with a case of the concentration ratio of less than 1.5 times. The concentration ratio may be 40 times or less, 20 times or less, or 15 times or less. When the concentration ratio is 40 times or less, the aggregation of the abrasive grains tends to be easily suppressed as compared with a case of the concentration ratio exceeding 40 times.

The (c) multiple liquid type has an advantage in that aggregation of abrasive grains and the like can be avoided by appropriately dividing each liquid (first liquid, second liquid, and the like) as compared with the (b) concentration type. Here, the components contained in each liquid are arbitrary. The (c) multiple liquid type (polishing liquid set for CMP) is a polishing liquid set for obtaining a polishing liquid by mixing the first liquid (slurry) with the second liquid (additive liquid). In the (c) multiple liquid type, components of the polishing liquid for CMP are stored separately in the first liquid and the second liquid, the first liquid contains abrasive grains and water, and the second liquid contains the nitrogen-containing aromatic compound and water. The first liquid and the second liquid may contain other component blended as necessary. In this case, to enhance dispersibility of the abrasive grains in the first liquid, an arbitrary acid or alkali may be blended in the first liquid to adjust the pH.

The polishing liquid of the (c) multiple liquid type is useful in a case of a combination of components in which polishing characteristics tend to deteriorate in a relatively short time due to aggregation of abrasive grains or the like when mixed. Note that at least one of the liquids (first liquid, second liquid, and the like) may be a concentration type from the viewpoint of cost reduction in storage and transportation. In this case, when the polishing liquid is used, each liquid and water may be mixed. The concentration ratio and pH of each liquid are arbitrary as long as the final mixture can have the same degree of liquid characteristics and polishing characteristics as that of the polishing liquid of the (a) normal type.

### <Polishing Method>

A polishing method of the present embodiment includes a polishing step of polishing a surface to be polished using the polishing liquid of the present embodiment. The polishing liquid used in the polishing step may be a polishing liquid obtained by mixing the first liquid with the second liquid of the above-described polishing liquid set. That is, the polishing method of the present embodiment may include the polishing step of polishing the surface to be polished using the polishing liquid obtained by mixing the first liquid with the second liquid of the above-described polishing liquid set.

In the polishing method of the present embodiment, a base substrate having a silicon oxide film on the surface thereof can be planarized by a CMP technique using a polishing liquid in which the content of each component, pH, or the like are adjusted. The polishing method of the present embodiment is suitable for polishing that requires high rate, high planarity, and low polishing scratches, such as polishing of an ILD film, and is suitable for use in polishing a large amount of ILD films in a short time. According to one form of the polishing method of the present embodiment, it is possible to efficiently obtain an effect of improving the polishing rate of silicon oxide in a blanket wafer and an effect of improving in-plane uniformity. According to one form of the polishing method of the present embodiment, since the polishing liquid of the present embodiment is used, it is possible to reduce occurrence of polishing scratches while achieving excellent dispersion stability of abrasive grains and achieving a sufficiently high polishing rate.

The polishing step may be a step in which the polishing liquid of the present embodiment is supplied between a base substrate and a polishing member (a member for polishing, a polishing pad and the like) and the base substrate is polished by the polishing member. The polishing method of the present embodiment is suitable for polishing a base substrate having a silicon oxide film on a surface thereof. Therefore, a surface to be polished may contain silicon oxide, and the polishing step may be a step of supplying the polishing liquid of the present embodiment between the silicon oxide film of the base substrate having the silicon oxide film on the surface thereof and the polishing member and polishing the silicon oxide film using the polishing member.

The polishing method of the present embodiment may have a form in which the surface to be polished has an uneven pattern constituted of a convex portion (a line portion) and a concave portion (a space portion), and the convex portion contains silicon oxide. The width of the convex portion in the uneven pattern may be 30 μm or less or 20 μm or less. The width of the convex portion in the uneven pattern may be 10 μm or more, or 20 μm or more. The sum of the width of the convex portion and the width of the concave portion in the uneven pattern may be 200 μm or less or 100 μm or less. The sum of the width of the convex portion and the width of the concave portion in the uneven pattern may be 80 μm or more or 100 μm or more.

The polishing method of the present embodiment is suitable for polishing a base substrate having a silicon oxide film on a surface thereof in a process of manufacturing a device. Examples of the device include individual semiconductors such as a diode, a transistor, a compound semiconductor, a thermistor, a varistor, and a thyristor; storage elements such as DRAM (dynamic random access memory), SRAM (static random access memory), EPROM (erasable programmable read-only memory), a mask ROM (mask read-only memory), EEPROM (electrical erasable programmable read-only memory), and a flash memory; theoretical circuit elements such as a microprocessor, a DSP, and an ASIC; an integrated circuit element such as a compound semiconductor typified by MMIC (monolithic microwave integrated circuit); a hybrid integrated circuit (hybrid IC); a light emitting diode; and a photoelectric conversion element such as a charge-coupled element.

According to one form of the polishing liquid of the present embodiment, a high polishing rate can be achieved without largely depending on the uneven shape of the surface to be polished. Therefore, the polishing method using this polishing liquid can also be applied to a base substrate in which it has been difficult to achieve a high polishing rate by a method using a conventional polishing liquid.

The polishing method of the present embodiment is suitable for planarization of a surface to be polished having a step (unevenness) on a surface thereof. Examples of a base substrate having such surface to be polished include a semiconductor device for logic. In addition, the polishing method of the present embodiment is suitable for polishing a surface including a portion at which a concave portion or a convex portion has a T shape or a lattice shape when viewed from above. For example, in the polishing method of the present embodiment, a silicon oxide film provided on a surface of a semiconductor device having a memory cell (DRAM, flash memory and the like) can also be polished at a high rate. It has been difficult to achieve a high polishing rate for these by a method using a conventional polishing liquid for CMP, and it is shown that a form of the polishing liquid of the present embodiment can achieve a high polishing rate without largely depending on the uneven shape of the surface to be polished.

The base substrate is not limited to the base substrate having only a silicon oxide film on the surface thereof, and may be a base substrate further having a silicon nitride film, a polycrystalline silicon film, or the like on the surface thereof in addition to the silicon oxide film. The base substrate may be a base substrate having an inorganic insulating film such as silicon oxide, glass, or silicon nitride; a film mainly containing polysilicon, Al, Cu, Ti, TiN, W, Ta, TaN, or the like; or the like on a wiring board having predetermined wiring.

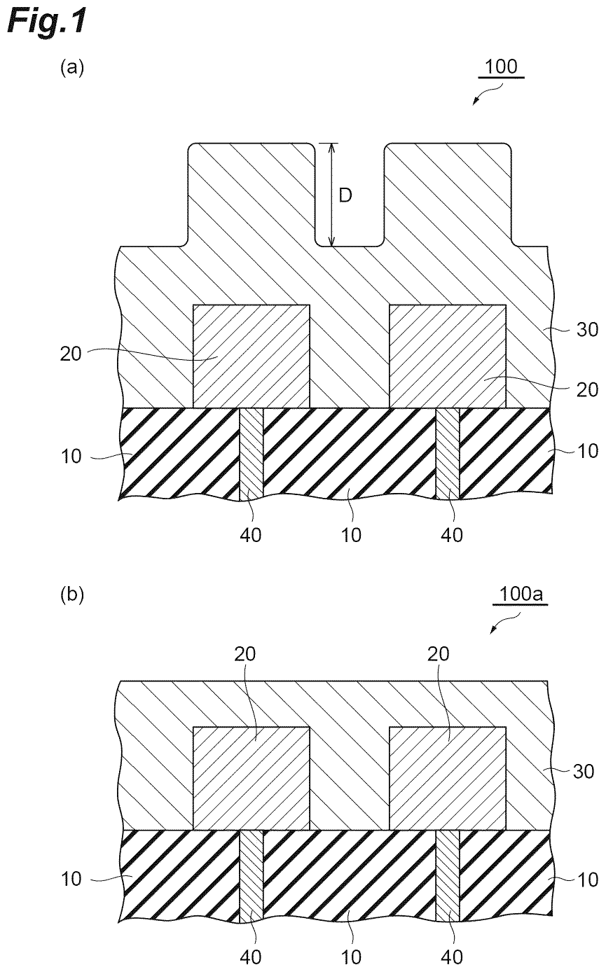

Hereinafter, as an example of a process including the polishing method of the present embodiment, a process of forming an ILD film (an interlayer insulating film) structure by CMP will be described. FIG. 1 is a schematic cross-sectional view illustrating a process of polishing an ILD film, and illustrates a process of forming the ILD film between wiring. FIG. 1(a) is a schematic cross-sectional view illustrating a base substrate before polishing. FIG. 1(b) is a schematic cross-sectional view illustrating a base substrate after polishing.

As illustrated in FIG. 1(a), in a base substrate 100 before polishing, a wiring 20 is formed on a lower substrate (not illustrated) having a predetermined lower wiring (not illustrated) via an ILD film 10, and a silicon oxide film 30 is formed so as to cover this wiring 20. Since the silicon oxide film 30 is formed on the ILD film 10 on which the wiring 20 is formed, a portion on the wiring 20 is higher than other portions, whereby a step D is generated on the surface of the silicon oxide film 30. The wiring 20 is connected to the lower wiring or the like by a contact plug 40 formed so as to penetrate the ILD film 10.

In the process of forming the ILD film structure, to eliminate the step D, unnecessary portions partially protruding on the surface of the silicon oxide film 30 are preferentially removed by CMP. To polish the silicon oxide film 30, the base substrate 100 is disposed on a polishing member so that the surface of the silicon oxide film 30 and the polishing member are brought into contact with each other, and the surface of the silicon oxide film 30 is polished by this polishing member. More specifically, the silicon oxide film 30 is polished by pressing the side of a surface to be polished (surface) of the silicon oxide film 30 against a polishing member of a polishing platen and relatively moving the surface to be polished and the polishing member while supplying a polishing liquid between the surface to be polished and the polishing member. As a result, the step D is eliminated, and finally, as shown in FIG. 1(b), the height of the portion of the wiring 20 on the surface of the silicon oxide film 30 and the height of the other portions become substantially the same as each other, thereby obtaining a base substrate 100a having the silicon oxide film 30 (ILD film) having a flat surface.

As a polishing device used for polishing, it is possible to use, for example, a device having a holder for holding a base substrate, a polishing platen to which a polishing pad is attached, and means for supplying a polishing liquid onto the polishing pad. Examples of the polishing device include a polishing device manufactured by Ebara Corporation (model numbers: EPO-111, EPO-222, F-REX200 and F-REX300) and a polishing device manufactured by Applied Materials (trade names: Mirra3400 and Reflexion). A constituent material of the polishing pad is not particularly limited, and for example, a general nonwoven fabric, foamed polyurethane, porous fluororesin, or the like can be used. In addition, the polishing pad may be grooved such that a polishing liquid accumulates thereon.

The polishing conditions are not particularly limited, but the rotation speed of the polishing platen may be 200 min⁻¹ or less from the viewpoint of preventing the base substrate from flying off. The pressure (processing load) applied to the base substrate may be 100 kPa or less from the viewpoint of easily suppressing polishing scratches on the polished surface. During the polishing, the polishing liquid may be continuously supplied to the polishing pad by a pump or the like. The supply amount for this is not limited, but the surface of the polishing pad may be constantly covered with the polishing liquid. After completion of the polishing, the base substrate may be sufficiently washed in flowing water, water droplets attached to the base substrate may be removed using a spin dryer or the like, and then may be dried.

By polishing as described above, unevenness on the surface can be eliminated, and a smooth surface can be obtained over the entire surface of the base substrate. In addition, a structure having a desired number of layers can be manufactured by repeating a step of forming a film and polishing this film a predetermined number of times.

The base substrate (structure) obtained as such can be used as various electronic components. Specific examples of an electronic component include: a semiconductor element; optical glass such as a photomask, a lens, and a prism; an inorganic conductive film such as ITO; an optical integrated circuit, an optical switching element, and an optical waveguide made of glass and a crystalline material; an end surface of an optical fiber; an optical single crystal such as a scintillator; a solid state laser single crystal; a sapphire substrate for a blue laser LED; a semiconductor single crystal such as SiC, GaP, or GaAs; a glass substrate for a magnetic disk; and a magnetic head.

### <Manufacturing Method and the Like>

The method of manufacturing a component of the present embodiment includes a component preparation step of obtaining a component using a base substrate (a polished member) polished by the polishing method of the present embodiment. The component of the present embodiment is a component obtained by the method of manufacturing a component of the present embodiment. The component of the present embodiment is not particularly limited, but may be an electronic component (for example, a semiconductor component such as a semiconductor package), may be a wafer (for example, a semiconductor wafer), and may be a chip (for example, a semiconductor chip). As one form of the method of manufacturing a component of the present embodiment, in a method of manufacturing an electronic component of the present embodiment, an electronic component is obtained using a base substrate polished by the polishing method of the present embodiment. As one form of the method of manufacturing a component of the present embodiment, in a method of manufacturing a semiconductor component of the present embodiment, a semiconductor component (for example, a semiconductor package) is obtained using a base substrate polished by the polishing method of the present embodiment. The method of manufacturing a component of the present embodiment may include a polishing step of polishing a base substrate by the polishing method of the present embodiment before the component preparation step.

The method of manufacturing a component of the present embodiment may include, as one form of the component preparation step, an individually dividing step of individually dividing a base substrate (a polished member) polished by the polishing method of the present embodiment. The individually dividing step may be, for example, a step of dicing a wafer (for example, a semiconductor wafer) polished by the polishing method of the present embodiment to obtain a chip (for example, a semiconductor chip). As one form of the method of manufacturing a component of the present embodiment, the method of manufacturing an electronic component of the present embodiment may include a step of obtaining an electronic component (for example, a semiconductor component) by individually dividing a base substrate polished by the polishing method of the present embodiment. As one form of the method of manufacturing a component of the present embodiment, the method of manufacturing a semiconductor component of the present embodiment may include a step of obtaining a semiconductor component (for example, a semiconductor package) by individually dividing a base substrate polished by the polishing method of the present embodiment.

The method of manufacturing a component of the present embodiment may include, as one form of the component preparation step, a connection step of connecting (for example, electrically connecting) a base substrate (a polished member) polished by the polishing method of the present embodiment to other body to be connected. The body to be connected to the base substrate polished by the polishing method of the present embodiment is not particularly limited, and may be a base substrate polished by the polishing method of the present embodiment, and may be a body to be connected different from the base substrate polished by the polishing method of the present embodiment. In the connection step, the base substrate and the body to be connected may be directly connected to each other (connected while the base substrate and the body to be connected are in contact with each other), and the base substrate and the body to be connected may be connected to each other via other member (conductive member or the like). The connection step can be performed before the individually dividing step, after the individually dividing step, or before and after the individually dividing step.

The connection step may be a step of connecting a polished surface of a base substrate polished by the polishing method of the present embodiment to a body to be connected, and may be a step of connecting a connection surface of a base substrate polished by the polishing method of the present embodiment to a connection surface of a body to be connected. The connection surface of the base substrate may be the polished surface polished by the polishing method of the present embodiment. By the connection step, a connection body having the base substrate and the body to be connected can be obtained. In the connection step, when the connection surface of the base substrate has a metal portion, the body to be connected may be brought into contact with the metal portion. In the connection step, when the connection surface of the base substrate has a metal portion and the connection surface of the body to be connected has a metal portion, the metal portions may be brought into contact with each other. The metal portion may contain copper.

A device (for example, an electronic device such as a semiconductor device) of the present embodiment has at least one selected from the group consisting of the base substrate polished by the polishing method of the present embodiment and the component of the present embodiment.

### EXAMPLES

Hereinafter, the present disclosure will be described in more detail with reference to Examples, but the present disclosure is not limited to Examples.

### <Production of Cerium Oxide Powder>

40 kg of cerium carbonate hydrate was divided into 10 alumina containers, and each of the containers was fired in air at 830° C. for two hours to obtain a total of 20 kg of yellowish white powder. This powder was subjected to phase identification by X-ray diffraction, and it was confirmed that this powder contained polycrystalline cerium oxide. The particle diameter of the powder obtained by firing was observed by SEM and was found to be in a range of 20 to 100 μm. Next, 20 kg of cerium oxide powder was dry-pulverized using a jet mill to obtain cerium oxide powder. The cerium oxide powder after pulverization had a specific surface area of 9.4 m²/g. The specific surface area was measured by a BET method.

### <Preparation of Slurry>

15.0 kg of the cerium oxide powder obtained as described above and 84.85 kg of deionized water were put in a container and mixed with each other. Next, 0.375 kg of an aqueous solution of ammonium polyacrylate (concentration: 40% by mass, molecular weight: about 10000) was added as a dispersant, and then stirring was performed for 10 minutes to obtain a cerium oxide mixed liquid. This cerium oxide mixed liquid was fed to another container over 30 minutes. Meanwhile, the cerium oxide mixed liquid was irradiated with ultrasonic waves at an ultrasonic frequency of 400 kHz in a pipe through which the cerium oxide mixed liquid was fed.

The above-described cerium oxide mixed liquid fed through ultrasonic irradiation was put into four 500 mL polyethylene containers by 500 g±5 g each. The cerium oxide mixed liquid in each container was centrifuged for two minutes under the condition that centrifugal force applied to the outer periphery was 500 G. After centrifugation was performed, supernatant fractions in the container were collected. The supernatant fractions collected from four containers were mixed with each other to obtain a slurry. The slurry contained cerium oxide particles of about 6.0% by mass based on the total mass of the slurry.

The slurry was diluted with pure water to obtain the content of abrasive grains having scattering intensity in a range suitable for measurement, thereby obtaining a sample for particle diameter measurement. As a result of measuring the average particle diameter of the abrasive grains of this sample using a laser diffraction/scattering type particle diameter distribution measuring device (trade name: Microtrac MT3300EXII manufactured by MicrotracBEL Corp.), the average particle diameter of the abrasive grains was 140 nm.

### <Preparation of Polishing Liquid for CMP>

### Examples 1 to 11

By mixing the above-described slurry, each additive, and deionized water as in the following procedure, a polishing liquid containing 0.50% by mass of the abrasive grains, additives (indole acetic acid, benzohydroxamic acid, quinaldic acid, or anthranilic acid) having contents as in the Table 1 below, and 0.005% by mass of the dispersant (ammonium polyacrylate mixed when preparing the above-described slurry) was obtained (balance: deionized water).

Specifically, each additive was dissolved in deionized water to obtain an additive solution. Next, the above-described slurry and the additive solution were mixed in the same amount and then stirred for 10 minutes to obtain a storage liquid for a polishing liquid in a concentrated state containing 5.00% by mass of the abrasive grains based on the total mass. The storage liquid for a polishing liquid contains the abrasive grains and the additives in an amount that is 10 times the abrasive grain content of 0.50% by mass in the final polishing liquid.

Then, the storage liquid for a polishing liquid was diluted 10 times with deionized water to obtain a polishing liquid. The average particle diameter of the abrasive grains in the polishing liquid of each Example measured by the same method as the average particle diameter of the abrasive grains in the above-described slurry was equal to the average particle diameter of the abrasive grains in the above-described slurry.

### Comparative Example 1

A polishing liquid containing 0.50% by mass of the abrasive grains and 0.005% by mass of the dispersant (ammonium polyacrylate mixed when preparing the above-described slurry) was obtained (balance: deionized water) in the same manner as in Examples except that no additive was used.

### <Measurement of Zeta Potential>

An appropriate amount of the polishing liquid was put into the trade name “DelsaNano C” manufactured by Beckman Coulter Inc., and measurement was performed twice at 25° C. An average value of the displayed zeta potentials was obtained as a zeta potential. In each of Examples and Comparative example, the zeta potential of the abrasive grains was negative as shown in Table 1.

<Measurement of pH>

The pH of the polishing liquid was measured under the following conditions. The results are shown in Table 1.

Measurement temperature: 25° C.

Measuring device: trade name: Model (D-71) manufactured by HORIBA, Ltd.

Measurement method: a pH meter was calibrated at three points using a phthalate pH standard solution (pH: 4.01), a neutral phosphate pH standard solution (pH: 6.86), and a borate pH standard solution (pH: 9.18) as pH standard solutions, an electrode of the pH meter was then placed in the polishing liquid, and pH after stabilization was measured by the measuring device above after 2 minutes or longer passed.

### <Evaluation of Dispersion Stability of Abrasive Grains>

The above-described polishing liquid immediately after the preparation was in a static state for one week (168 hours), and the average particle diameter of the abrasive grains after the lapse of one week immediately after the preparation was measured by the same method as the average particle diameter of the abrasive grains in the above-described slurry. “[(the average particle diameter in the polishing liquid after the lapse of one week−the average particle diameter of the abrasive grains in the above-described slurry)/the average particle diameter of the abrasive grains in the above-described slurry]×100” was calculated as a change rate of the average particle diameter of the abrasive grains after the lapse of one week. A case in which the change rate of the average particle diameter of the abrasive grains after the lapse of one week was 4% or less was determined as “A”, and a case in which the change rate of the average particle diameter of the abrasive grains after the lapse of one week was more than 4% was determined as “B”. The results are shown in Table 1.

### <Evaluation of Polishing Characteristics>

### (Preparation of Wafer for Evaluation)

As a blanket wafer (BKW), φ200 mm unpatterned wafer having a silicon oxide film (SiO₂, initial film thickness: 1000 nm) on the surface thereof and φ200 mm unpatterned wafer having a silicon nitride film (SiN, initial film thickness: 200 nm) on the surface thereof were prepared.

As a patterned wafer (PTW), a wafer with a test pattern of a silicon oxide film (initial film thickness: 600 nm) having an uneven pattern on the surface thereof (model number: Sematech864 manufactured by Advantec Co., Ltd., φ200 mm) was prepared. A convex portion (a line portion) has an initial step 500 nm higher than a concave portion (a space portion), and the convex portion has a silicon nitride film (initial film thickness: 140 nm) as a stopper which is the underlayer of the silicon oxide film assuming evaluation for shallow trench isolation. The patterned wafer has a plurality of 20 mm×20 mm die units, and has a plurality of 4 mm×4 mm unit areas in each die unit. The patterned wafer has, as a 4 mm×4 mm unit area, a region having parallel line patterns with a pitch of 100 μm width and a Line/Space (L/S) of 10 μm/90 μm (density of the convex portion: 10%) to 90 μm/10 μm (density of the convex portion: 90%) in increments of 10 μm.

### (Polishing Procedure)

The above-described wafer for evaluation was polished using a polishing device (trade name: Mirra3400 manufactured by Applied Materials). The above-described wafer for evaluation was set on a holder having a suction pad for attaching a base substrate. A porous urethane resin polishing pad (K-groove, manufactured by DuPont (Dow), model number: IC-1010) was attached to a polishing platen having a diameter of 500 mm.

The above-described holder was placed on the polishing pad while a surface to be polished of the above-described wafer for evaluation faced downward. The inner tube pressure, the retainer ring pressure, and the membrane pressure were set to 14 kPa, 21 kPa, and 14 kPa, respectively.

Then, while the above-described polishing liquid was dropped on the polishing pad attached to the above-described polishing platen at a flow rate of 200 mL/min, the polishing platen and the wafer for evaluation were rotated at 93 min⁻¹ and 87 min⁻¹, respectively, to polish the surface to be polished. The blanket wafer was polished for 30 seconds. In the patterned wafer, a time during which the silicon nitride film as an underlayer of the silicon oxide film was not exposed at the convex portion in the region of L/S=20 μm/80 μm was set as a polishing time in a range of 20 to 60 seconds according to the polishing rate evaluated with the blanket wafer, and polishing was performed within such polishing time. Subsequently, the wafer for evaluation after polishing was thoroughly washed with pure water using a PVA brush (polyvinyl alcohol brush), and then was dried.

### (Evaluation of Polishing Rate)

Using a light interference type film thickness measuring device (trade name: AFT-5100 manufactured by Nanometrics Japan Co., Ltd.), the amount of change in the film thickness of a film to be polished before and after polishing was measured as follows, and the polishing rate was obtained. In addition, the polishing rate ratio of silicon oxide at the convex portion in the patterned wafer with respect to silicon oxide in the blanket wafer (PTW/BKW) was calculated. The results are shown in Table 1.

In the blanket wafer, the film thickness change amount was measured at 41 measurement points in total including a center point of the wafer and each point at 5 mm intervals in a diameter direction from the center point (20 points on both sides with the center point as a boundary) (a next measurement point after a measurement point of 95 mm from the center was a position of 97 mm from the center). At these 41 points, the film thickness change amount in the polishing time for 30 seconds was measured, and the average value thereof was obtained as the polishing rate of the blanket wafer.

For the patterned wafer, the film thickness change amount at the convex portion in the region of L/S=20 μm/80 μm was measured to obtain the polishing rate of the patterned wafer. The film thickness change amount at one central portion of one unit area (4 mm×4 mm) of L/S=20 μm/80 μm was measured in the die unit (20 mm×20 mm) at the center of the patterned wafer.

TABLE 1

| | | | | | | | | | | | | | Compar- |
|---|---|---|---|---|---|---|---|---|---|---|---|---|---|
| | | | | | | | | | | | | | ative |
| | | Example | | | | | | | | | | | Example |
| | | 1 | 2 | 3 | 4 | 5 | 6 | 7 | 8 | 9 | 10 | 11 | 1 |
| Abrasive | Zeta | <−40 | −50 to | −60 to | −60 to | −60 to | <−40 | −45 to | −50 to | <−40 | −45 to | −50 to | −60 to |
| grains | potential | | −45 | −50 | −50 | −50 | | −40 | −45 | | −40 | −45 | −55 |
| | [mV] | | | | | | | | | | | | |
| Indole | Content | 0.010 | 0.005 | — | — | — | — | — | — | — | — | — | — |
| acetic acid | [mass %] | | | | | | | | | | | | |
| Benzo- | | — | — | 0.050 | 0.010 | 0.005 | — | — | — | — | — | — | — |
| hydro- | | | | | | | | | | | | | |
| xamic | | | | | | | | | | | | | |
| acid | | | | | | | | | | | | | |
| Quinalic | | — | — | — | — | — | 0.020 | 0.010 | 0.005 | — | — | — | — |
| acid | | | | | | | | | | | | | |
| Anthranilic | | — | — | — | — | — | — | — | — | 0.020 | 0.010 | 0.005 | — |
| acid | | | | | | | | | | | | | |
| pH | | 5.2 | 6.3 | 7.6 | 8.0 | 8.1 | 5.0 | 5.9 | 6.9 | 4.9 | 3.3 | 6.1 | 8.2 |
| Dispersion | | B | A | A | A | A | B | A | A | B | A | A | A |
| stability of | | | | | | | | | | | | | |
| abrasive grains | | | | | | | | | | | | | |
| Polishing | BKW: | 179.7 | 228.5 | 231.5 | 263.6 | 237.0 | 228.1 | 135.4 | 198.0 | 241.8 | 140.1 | 220.0 | 152.0 |
| rate | SiO₂ | | | | | | | | | | | | |
| [nm/min] | BKW: | 15.0 | 15.0 | 10.8 | 12.4 | 11.8 | 20.1 | 14.4 | 17.5 | 28.9 | 15.3 | 15.8 | 15.0 |
| | SiN | | | | | | | | | | | | |
| | PTW: | 270.1 | 213.2 | 412.7 | 352.4 | 259.6 | 379.5 | 264.2 | 175.7 | 372.8 | 301.1 | 193.8 | 94.0 |
| | SiO₂ | | | | | | | | | | | | |
| Polishing | PTW/ | 1.50 | 0.93 | 1.78 | 1.34 | 1.10 | 1.66 | 1.95 | 0.89 | 1.54 | 2.15 | 0.88 | 0.62 |
| rate ratio | BKW | | | | | | | | | | | | |
| | (SiO₂) | | | | | | | | | | | | |

### REFERENCE SIGNS LIST

10 . . . . ILD film, 20 . . . wiring, 30 . . . silicon oxide film, 40 . . . contact plug, 100, 100a . . . base substrate, D . . . step.

1. A polishing liquid for CMP, the polishing liquid comprising: abrasive grains; a nitrogen-containing compound having an aromatic ring; and water, wherein
the abrasive grains include cerium-based particles, and
the abrasive grains have a negative zeta potential.

2. The polishing liquid for CMP according to claim 1, wherein the cerium-based particles contain cerium oxide.

3. The polishing liquid for CMP according to claim 1, wherein the nitrogen-containing compound includes a compound having an amino group bonded to an aromatic ring.

4. The polishing liquid for CMP according to claim 3, wherein the nitrogen-containing compound includes anthranilic acid.

5. The polishing liquid for CMP according to claim 1, wherein the nitrogen-containing compound includes a compound having a hydroxyamide group bonded to an aromatic ring.

6. The polishing liquid for CMP according to claim 5, wherein the nitrogen-containing compound includes benzohydroxamic acid.

7. The polishing liquid for CMP according to claim 1, wherein the nitrogen-containing compound includes an indole compound.

8. The polishing liquid for CMP according to claim 7, wherein the nitrogen-containing compound includes indole acetic acid.

9. The polishing liquid for CMP according to claim 1, wherein the nitrogen-containing compound includes a quinoline compound.

10. The polishing liquid for CMP according to claim 9, wherein the nitrogen-containing compound includes quinaldic acid.

11. The polishing liquid for CMP according to claim 1, wherein a content of the nitrogen-containing compound is 0.001 to 5% by mass.

12. The polishing liquid for CMP according to claim 1, wherein pH is 4.0 to 9.0.

13. A polishing liquid set for CMP, wherein components of the polishing liquid for CMP according to claim 1 are stored separately in a first liquid and a second liquid, in which the first liquid contains the abrasive grains and water, and the second liquid contains the nitrogen-containing compound and water.

14. A polishing method comprising a step of polishing a surface to be polished using the polishing liquid for CMP according to claim 1.

15. The polishing method according to claim 14, wherein the surface to be polished contains silicon oxide.

16. The polishing liquid for CMP according to claim 1, wherein a zeta potential of the abrasive grains is less than −40 mV.

17. The polishing liquid for CMP according to claim 1, wherein an average particle diameter of the abrasive grains is more than 100 nm.

18. The polishing liquid for CMP according to claim 1, wherein the nitrogen-containing compound includes at least one selected from the group consisting of indole acid, alkylindole, phenylindole, hydroxyindole, carboxyindole, alkoxyindole, aminoindole, nitroindole, nitrile indole, and chloroindole.

19. The polishing liquid for CMP according to claim 1, wherein pH is more than 6.0.

20. The polishing liquid for CMP according to claim 1, wherein pH is less than 6.0.
